(19) United States
(12) Patent Application Publication
(10) Pub. No.: US 2026/0372064 A1
(43) Pub. Date: Nov. 19, 2026

(54) SEMICONDUCTOR PACKAGES AND METHODS OF FORMING THE SAME

(71) Applicant: Taiwan Semiconductor Manufacturing Co., Ltd., Hsinchu (TW)

(72) Inventors: Ching-Yu Huang, Hsinchu (TW); Ting-Chu Ko, Hsinchu (TW)

(21) Appl. No.: 19/752,039

(22) Filed: Jul. 23, 2026

Related U.S. Application Data
(62) Division of application No. 18/192,521, filed on Mar. 29, 2023.

(51) Int. Cl. H10W 20/41; H10D 84/83; H10W 20/00; H10W 20/42; H10W 72/00; H10W 72/90

(52) U.S. Cl. CPC H10W 20/435; H10D 84/83; H10W 20/023; H10W 20/42; H10W 72/019; H10W 72/90; H10W 72/926; H10W 72/936

(57) ABSTRACT

A method includes attaching a front-side of a first die to a wafer, the first bond pad being along a back-side of the first die, the wafer comprising a substrate and a transistor along the substrate, the transistor facing the wafer, the first die comprising: a first bond pad; a first back-side interconnect structure; a first front-side interconnect structure; a first semiconductor substrate interposed between the first back-side interconnect structure and the first front-side interconnect structure; and a first transistor along the first semiconductor substrate, the first transistor facing the front-side of the first die; forming a second bond pad over the first front-side interconnect structure; and attaching a second front-side of a second die to the second bond pad of the first die, the second die comprising a second semiconductor substrate and a second transistor, the second transistor facing the front-side of the second die.

### PRIORITY CLAIM AND CROSS-REFERENCE

This application is a divisional of U.S. Patent Application No. 18/192,521, filed on Mar. 29, 2023, which application is incorporated herein by reference.

### BACKGROUND

The semiconductor industry has experienced rapid growth due to ongoing improvements in the integration density of a variety of electronic components (e.g., transistors, diodes, resistors, capacitors, and the like). For the most part, improvement in integration density has resulted from iterative reduction of minimum feature size, which allows more components to be integrated into a given area. As the demand for shrinking electronic devices has grown, a tendency for smaller and more creative packaging techniques of semiconductor dies has emerged.

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together in order to form a functional device. Such bonding processes utilize sophisticated techniques, and improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C illustrate cross-sectional views of intermediate steps during processes for forming an integrated circuit die, in accordance with some embodiments.

FIGS. 2A-2E illustrate cross-sectional views of intermediate steps during processes for forming an integrated circuit die, in accordance with some embodiments.

FIGS. 3A-3B illustrate cross-sectional views of intermediate steps during processes for forming an integrated circuit die, in accordance with some embodiments.

FIGS. 4-8 illustrate cross-sectional views of intermediate steps during processes for forming a semiconductor package, in accordance with some embodiments.

FIGS. 9-12 illustrate layouts of various semiconductor packages, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide improved methods of forming multi-level semiconductor packages with enhanced electrical connectivity between component integrated circuit dies. In accordance with some embodiments, integrated circuit dies are formed at the wafer level and assembled into a semiconductor package having three or more tiers. For example, a first integrated circuit may be formed in a wafer, a second integrated circuit formed in a die (e.g., a middle die) may be attached to the wafer, and a third integrated circuit formed in another die (e.g., a top die) may be attached to the middle die. In particular, the middle die may be formed with front-side and back-side interconnect structures and with various conductive vias to facilitate high density electrical connection there-between. As a result of the high density electrical connection within the middle die, the middle die can also have high density electrical connection with both the wafer and the top die. In accordance with the various embodiments, the semiconductor packages may have a larger variety of layouts, wherein each of the semiconductor packages may be assembled at greater efficiency and increased yield (e.g., thereby reducing costs). In addition, component integrated circuit dies may achieve high performance with smaller footprints and with an improved performance by having higher density of direct electrical connections between one another.

Various embodiments are described below in a particular context. Specifically, multiple levels of chips on wafer on substrate-type of system on integrated chip (SoIC) package is described. However, various embodiments may also be applied to other types of packaging technologies, such as, chip-on-wafer-on-substrate (CoWoS^{®}) packages, die-die-substrate stacked packages, integrated fan-out (InFO) packages, and/or other types of semiconductor packages.

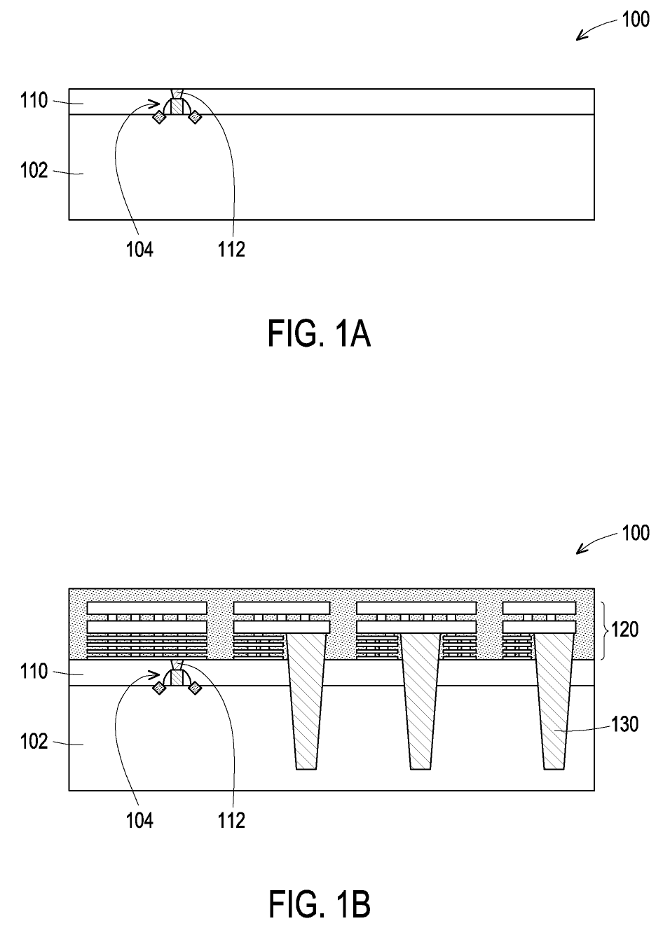

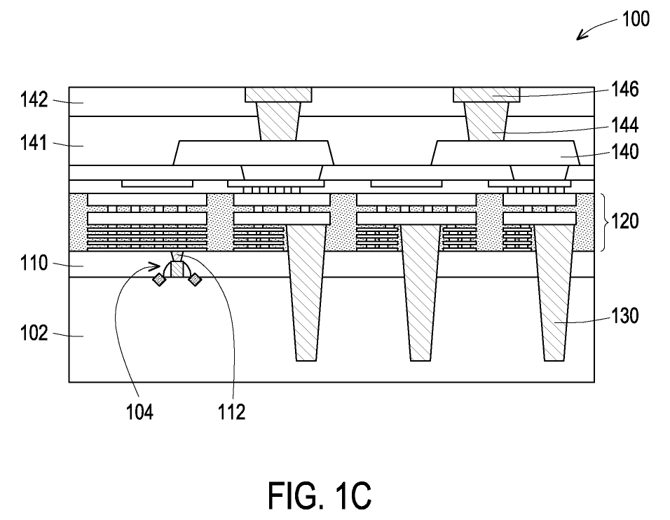

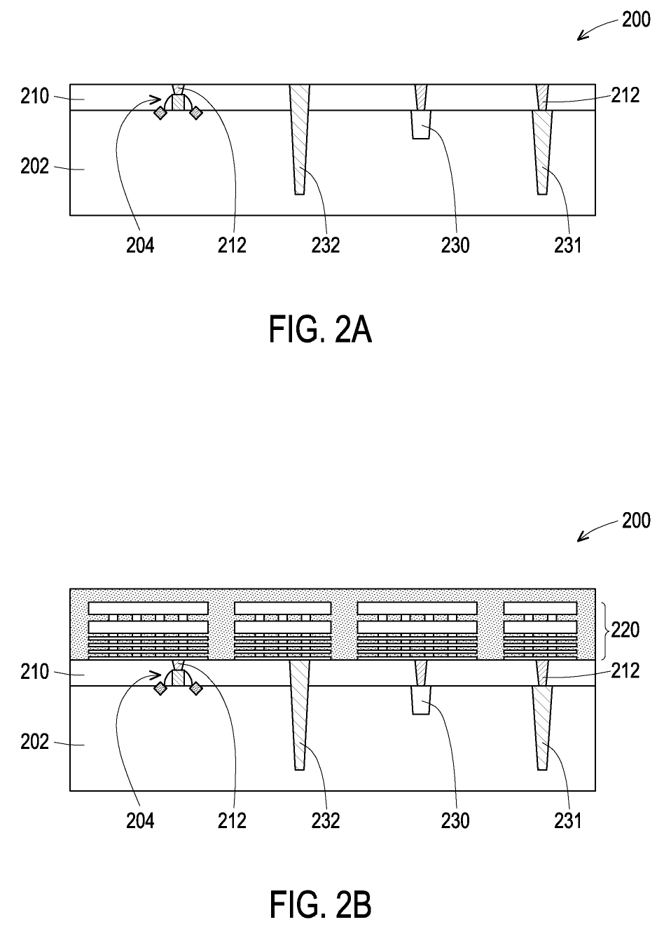

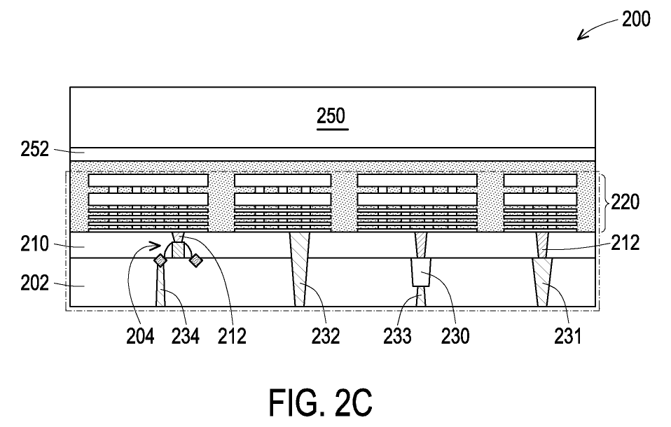

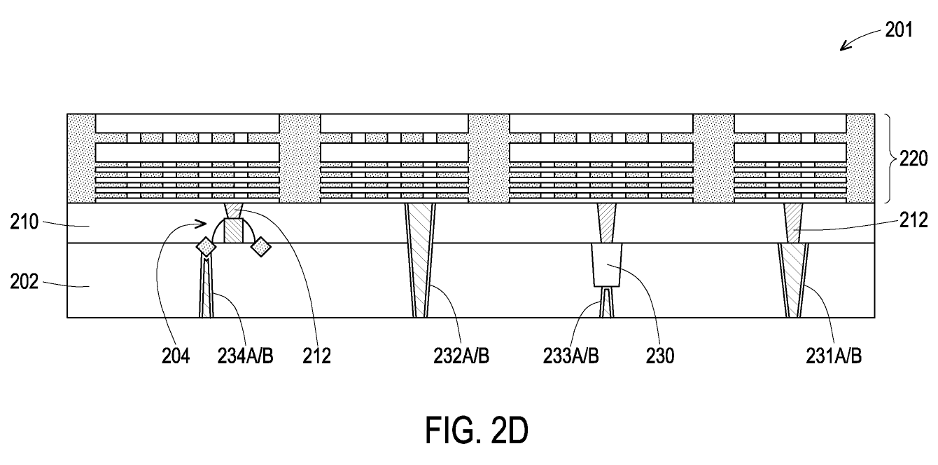

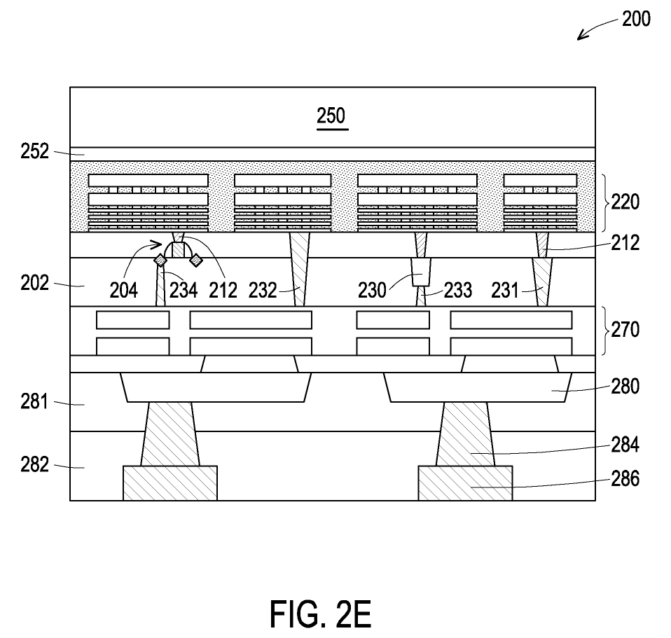

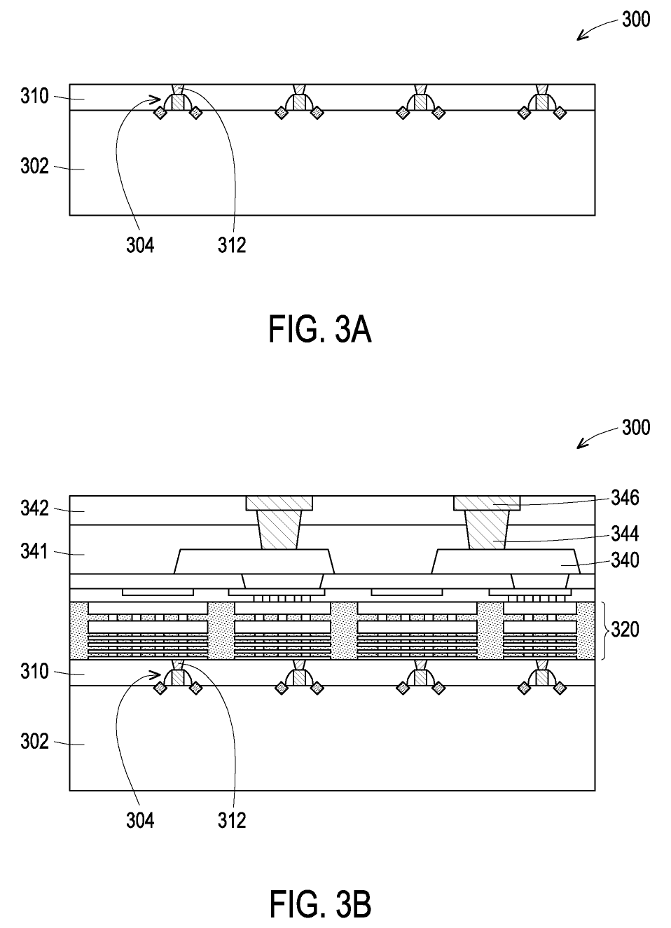

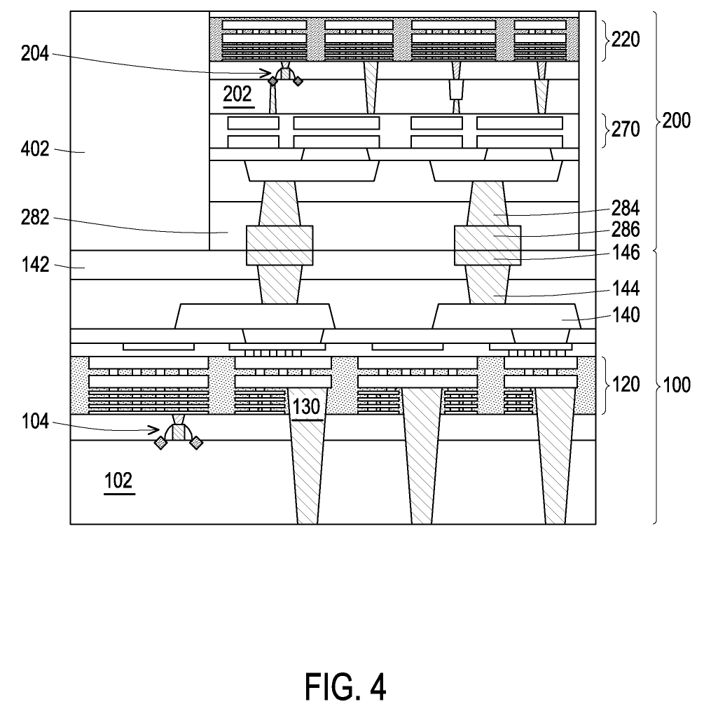

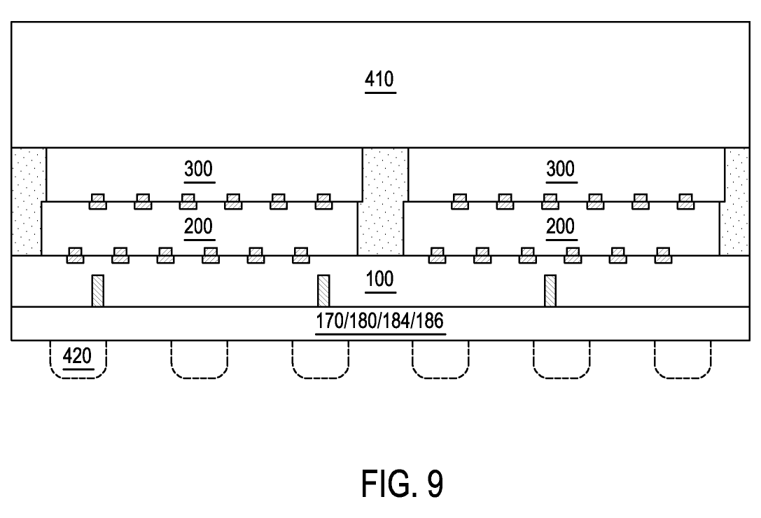

FIGS. 1A-1C illustrate cross-sectional views in the formation of an exemplary wafer (e.g., a bottom wafer 100) to be subsequently included in a lower tier of a multi-level semiconductor package, in accordance with various embodiments. FIGS. 2A-2E illustrate cross-sectional views in the formation of an exemplary integrated circuit die (e.g., a middle die 200) to be subsequently included in one or more middle tiers of the multi-level semiconductor package, in accordance with various embodiments. FIGS. 3A-3B illustrate cross-sectional views in the formation of an exemplary integrated circuit die (e.g., a top die 300) to be subsequently included in an upper tier of the multi-level semiconductor package, in accordance with various embodiments. FIGS. 4-8 illustrate cross-sectional views in the formation of an embodiment layout of the multi-level semiconductor package including the bottom wafer 100, one or more middle dies 200, and one or more top dies 300, in accordance with various embodiments. FIGS. 9-12 illustrate various additional embodiment layouts of the multi-level semiconductor package, which may be formed using the same or similar process steps. As discussed further below, the semiconductor package may be arranged in a variety of layouts not specifically illustrated and are fully intended to be within the scope of the disclosure.

FIGS. 1A-1C illustrate cross-sectional views of forming a bottom wafer 100, in accordance with some embodiments. The bottom wafer 100 may include a plurality of integrated circuit dies which may be packaged and singulated in subsequent processing to form various embodiments of a semiconductor package (which may also be referred to as a packaged semiconductor device). The integrated circuit die may be a logic die (e.g., a central processing unit (CPU), a graphics processing unit (GPU), a system-on-a-chip (SoC), an application processor (AP), a microcontroller, or the like); a memory die (e.g., a dynamic random access memory (DRAM) die, a static random access memory (SRAM) die, or the like); a power management die (e.g., a power management integrated circuit (PMIC) die); a radio frequency (RF) die; a sensor die; a micro-electro-mechanical-system (MEMS) die; a signal processing die (e.g., a digital signal processing (DSP) die); a front-end die (e.g., an analog front-end (AFE) die); or a combination thereof.

In FIG. 1A, various devices 104 may be formed along a front-side of a substrate 102. For example, the substrate 102 may include a semiconductor substrate, such as silicon, doped or un-doped, or an active layer of a semiconductor-on-insulator (SOI) substrate. The semiconductor substrate may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may be used. The substrate 102 has an active surface (e.g., the surface facing upwards in FIG. 1A on which the devices 104 are formed), which may be referred to as a front-side, and an inactive surface (e.g., the surface facing downwards in FIG. 1A), which may be referred to as a back-side.

The devices 104 (represented by a transistor) may be formed at the front-side of the substrate 102. The devices 104 may be active devices (e.g., transistors, diodes, or the like), capacitors, resistors, or the like. An inter-layer dielectric (ILD) 110 is on the front-side of the substrate 102. The ILD 110 surrounds and may cover the devices 104. The ILD 110 may include one or more dielectric layers formed of materials such as phosphosilicate glass (PSG), boro-silicate glass (BSG), boron-doped phosphosilicate glass (BPSG), un-doped silicate glass (USG), or the like.

Conductive plugs 112 may be formed extending through the ILD 110. The conductive plugs 112 may be electrically and physically coupled to the devices 104. In embodiments in which the devices 104 are transistors, the conductive plugs 112 may be coupled to gates and/or source/drain regions (source/drain regions may refer to a source or a drain, individually or collectively, dependent upon the context) of the transistors. The conductive plugs 112 may be formed of tungsten, cobalt, nickel, copper, silver, gold, aluminum, the like, or combinations thereof.

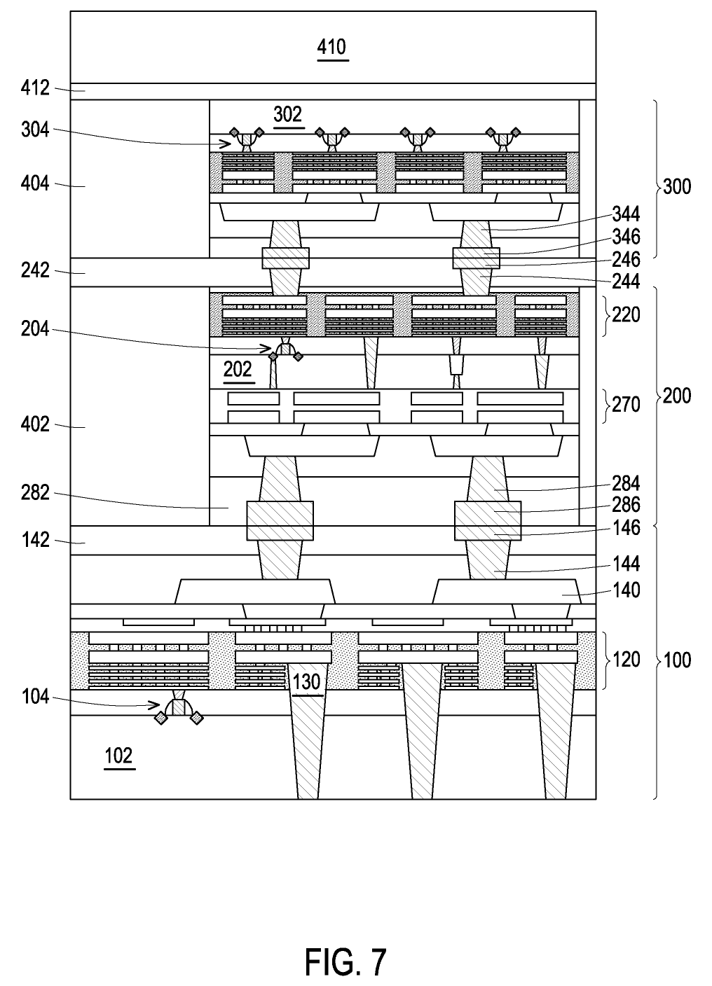

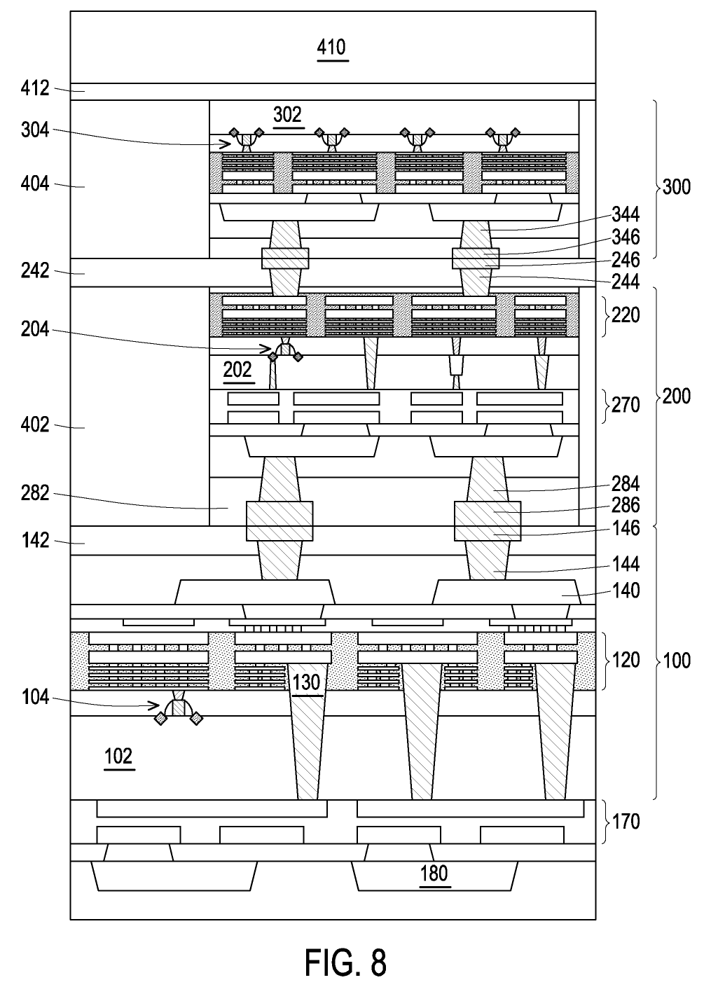

In FIG. 1B, an interconnect structure 120 is formed over the substrate 102 and the devices 104, and conductive vias 130 may be formed extending through the ILD 110 and into the substrate 102. In some embodiments, the conductive vias 130 may be connected to an upper portion of the interconnect structure 120 and extend through a lower portion of the interconnect structure 120. In some embodiments (not specifically illustrated), the conductive vias 130 may be connected to the lower portion of the interconnect structure 120. The conductive vias 130 may be subsequently exposed through the back-side of the substrate 102, and may be used to provide electrical connections through the substrate 102 (e.g., between the front-side and the back-side of the substrate 102) (see, e.g., FIGS. 7-8). As such, the conductive vias 130 may also be referred to as through substrate vias (TSVs).

In some embodiments, the conductive vias 130 may be formed through the ILD 110 and a portion of the substrate 102. The recesses may be formed by etching, milling, laser techniques, a combination thereof, or the like. A liner (not specifically illustrated) may be formed in the recesses, such as by thermal oxidation, atomic layer deposition (ALD), chemical vapor deposition (CVD), or the like. The liner may be a dielectric material and include oxides, such as silicon oxide, silicon oxynitride, or the like. A barrier layer and/or an adhesion layer (not specifically illustrated) may then be conformally deposited in the recesses (e.g., along the liner), such as by CVD, ALD, physical vapor deposition (PVD), a combination thereof, or the like. The barrier layer and/or the adhesion layer may be formed of titanium, titanium nitride, tantalum, tantalum nitride, or the like. A conductive fill material is deposited on the barrier layer and/or the adhesion layer and fills the recesses. The conductive fill material may be deposited by an electro-chemical plating process, CVD, ALD, PVD, a combination thereof, or the like. Examples of conductive fill material include copper, a copper alloy, silver, gold, tungsten, ruthenium, cobalt, aluminum, nickel, a combination thereof, or the like. Excess portions of the conductive fill material, the adhesion layer, the barrier layer, and/or the liner, such as portions extending along top surfaces of the ILD 110 and/or the substrate 102 are removed from the surfaces of the ILD 110 and/or the substrate 102 by a planarization process, such as a chemical-mechanical polish (CMP), a grinding process, an etch-back process, or the like. Remaining portions of the barrier layer, the adhesion layer, and/or the conductive fill material form the conductive vias 130.

The interconnect structure 120 is formed on the ILD 110 and connected to the conductive plugs 112. The interconnect structure 120 interconnects the devices 104 to form integrated circuits. In some embodiments, the interconnect structure 120 may be formed of metallization patterns in dielectric layers on the ILD 110. The metallization patterns include metal lines and vias formed in one or more low-k dielectric layers. The metallization patterns of the interconnect structure 120 are electrically coupled to the devices 104 by the conductive plugs 112, and are electrically connected to the conductive vias 130.

In FIG. 1C, metal pads 140 (e.g., aluminum pads), bond pad vias 144, and bond pads 146, to which external connections are made, are formed over the interconnect structure 120. The metal pads 140 are on the front-side of the substrate 102, such as in and/or on the interconnect structure 120. As illustrated, the metal pads 140 are disposed over and electrically connected to the metallization layers of the interconnect structure 120. The metal pads 140 may be within one or more dielectric layers 141 and comprise a metal, such as aluminum, copper, or the like. For example, the dielectric layers 141 may include a silicon oxide and/or a silicon nitride, such as silicon oxynitride (SiON), silicon carbide (SiC), or any suitable material. The metal pads 140 may be considered part of the interconnect structure 120.

In accordance with some embodiments, the bond pad vias 144 and the bond pads 146 are formed over the metal pads 140 and the interconnect structure 120. The bond pad vias 144 and the bond pads 146 may be formed using single or dual damascene processes. For example, a dielectric bond layer 142 may be formed over the metal pads 140, and the dielectric bond layer 142 and the dielectric layers 141 may be etched to form recesses. The recesses may then be filled to form the bond pad vias 144 and the bond pads 146 similarly as described above in connection with the conductive vias 130.

For example, the dielectric bond layer 142 may be formed over the interconnect structure 120 and the metal pads 140. The dielectric bond layer 142 may be one or more dielectric layers that include an oxide such as silicon oxide, a nitride such as silicon nitride, or combinations thereof, and may be formed using CVD, ALD, the like, or a suitable method. In accordance with some embodiments, the dielectric bond layer 142 includes a silicon oxide layer. The dielectric bond layer 142 and the one or more underlying dielectric layers 141 are etched to form recesses that expose the metal pads 140. In embodiments that use a dual damascene process, the recesses may be formed using multiple etch processes, and the bond pad vias 144 and the bond pads 146 may be simultaneously formed similarly as described above in connection with the conductive vias 130. For example, a conductive liner and a conductive material may be deposited in the recesses and over the dielectric bond layer 142, and a planarization process may be performed to remove excess portions of the conductive material and the conductive liner from a top surface of the dielectric bond layer 142. In some embodiments (not specifically illustrated), the bond pad vias 144 may be formed through the dielectric layers 141, and the bond pads 146 may be subsequently formed through the dielectric bond layer 142.

In some embodiments (not specifically illustrated), the bond pads 146 may be formed after the bond pad vias 144, and the bond pads 146 may be microbumps, ball grid array (BGA) connectors, solder balls, metal pillars, controlled collapse chip connection (C4) bumps, electroless nickel-electroless palladium-immersion gold technique (ENEPIG) formed bumps, or the like. The bond pads 146 may include a conductive material such as solder, copper, aluminum, gold, nickel, silver, palladium, tin, the like, or a combination thereof. In some embodiments, the bond pads 146 are formed by initially forming a layer of solder through evaporation, electroplating, printing, solder transfer, ball placement, or the like. Once a layer of solder has been formed on the structure, a reflow may be performed in order to shape the material into the desired bump shapes. In addition, the dielectric bond layer 142 may be a polymer such as PBO, polyimide, BCB, or the like; a nitride such as silicon nitride or the like; an oxide such as silicon oxide, PSG, BSG, BPSG, or the like; the like, or a combination thereof. The dielectric bond layer 142 may be formed by spin coating, lamination, CVD, or the like. Initially, the dielectric bond layer 142 may bury the bond pads 146, such that a topmost surface of the dielectric bond layer 142 is above topmost surfaces of the bond pads 146. In some embodiments, solder regions may be formed on the bond pads 146, and the dielectric bond layer 142 may bury the solder regions. In some embodiments, the bond pads 146 are exposed through or protrude above the dielectric bond layer 142 during formation of the bottom wafer 100. In some embodiments, the bond pads 146 remain buried and are exposed during a subsequent process for packaging the bottom wafer 100. Exposing the bond pads 146 may include removing any solder regions that may be present on the bond pads 146.

FIGS. 2A-2E illustrate cross-sectional views of forming a middle die 200, in accordance with some embodiments. The middle die 200 includes an integrated circuit die formed in a wafer, which may include different device regions that are singulated in subsequent steps to form a plurality of singulated integrated circuit dies. The wafer including the middle die 200 may be processed according to applicable manufacturing processes to form singulated middle dies 200. The middle die 200 may be formed similarly as described above in connection with analogous features of the bottom wafer 100 unless otherwise specified. The middle die 200 may be a logic die (e.g., a CPU), a GPU), an SoC, an AP, a microcontroller, or the like); a memory die (e.g., a DRAM die, an SRAM die, or the like); a power management die (e.g., a PMIC die); an RF die; a sensor die; a MEMS die; a signal processing die (e.g., a DSP die); a front-end die (e.g., an AFE die); or a combination thereof.

As discussed in greater detail below, the middle die 200 may include one or more of four general types of conductive vias (e.g., through vias, such as TSVs) extending from a front-side to a back-side of a substrate 202 of the middle die 200. As discussed in greater detail below, a first via 231 may be formed using a via-first process, wherein conductive material of the first via 231 is formed in the front-side of the substrate 202 of the middle die 200 before formation of devices 204 and an overlying interconnect structure 220. In addition, a second via 232 may be formed using a via-middle process, wherein conductive material of the second via 232 is also formed in the front-side of the substrate 202 of the middle die 200 after formation of the devices 204 and either before or during formation of the overlying interconnect structure 220. Further, a third via 233 and a fourth via 234 may be formed using via-last processes, wherein conductive materials of the third via 233 and the fourth via 234 are formed in the back-side of the substrate 202 of the middle die 200.

In FIG. 2A, the devices 204 are formed in a front-side of the substrate 202, and the first vias 231 and the second vias 232 may be formed in the front-side of the substrate 202. In addition, buried contacts 230, which subsequently formed third vias 233 may connect to, may also be formed in the front-side of the substrate 202. For example, the substrate 202 may include a semiconductor substrate, such as silicon, doped or un-doped, or an active layer of a semiconductor-on-insulator (SOI) substrate. The semiconductor substrate may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may be used. The substrate 202 has an active surface (e.g., the surface facing upwards in FIG. 2A on which the devices 204 are formed), which may be referred to as the front-side, and an inactive surface (e.g., the surface facing downwards in FIG. 2A), which may be referred to as the back-side. The devices 204 (represented by a transistor) may be formed at the front-side of the substrate 202. The devices 204 may be active devices (e.g., transistors, diodes, or the like), capacitors, resistors, or the like.

The first vias 231 are a first type of conductive via and are formed extending into the substrate 202. The first vias 231 may be subsequently exposed through the back-side of the substrate 202, and may be used to provide electrical connections through the substrate 202 (e.g., between the front-side and the back-side of the substrate 202) (see FIGS. 2C-2E). As such, the first vias 231 may also be referred to as TSVs. In some embodiments, the first vias 231 are formed before formation of the devices 204.

The second vias 232 are a second type of conductive via and are formed extending through the ILD 210 and into the substrate 202, similarly as described above in connection with the conductive vias 130. In some embodiments, the second vias 232 may be connected to a lower portion of the subsequently formed interconnect structure 220 (see FIG. 2B). In some embodiments (not specifically illustrated), the second vias 232 may be connected to an upper portion of the interconnect structure 220, similarly as described in connection with the conductive vias 130 of the bottom wafer 100. The second vias 232 may be subsequently exposed through the back-side of the substrate 202, and may be used to provide electrical connections through the substrate 202 (e.g., between the front-side and the back-side of the substrate 202) (see FIGS. 2C-2E). As such, the second vias 232 may also be referred to as TSVs.

The first vias 231 and the second vias 232 may be formed similarly as one another and as the conductive vias 130, unless otherwise specified. As discussed above, it should be noted that the first vias 231 are formed before depositing the ILD 210, and the second vias 232 are formed after depositing the ILD 210. For example, the first vias 231 are formed by forming recesses in the substrate 202, and the second vias 232 are formed by forming recesses in the ILD 210 and the substrate 202. The respective recesses may be formed by etching, milling, laser techniques, a combination thereof, or the like. A liner (not specifically illustrated) may be formed in the recesses, such as by thermal oxidation, atomic layer deposition (ALD), chemical vapor deposition (CVD), or the like. The liner may be a dielectric material and include oxides, such as silicon oxide, silicon oxynitride, or the like. A barrier layer and/or an adhesion layer (not specifically illustrated) may then be conformally deposited in the recesses (e.g., along the liner), such as by CVD, ALD, physical vapor deposition (PVD), a combination thereof, or the like. The barrier layer and/or the adhesion layer may be formed of titanium, titanium nitride, tantalum, tantalum nitride, or the like. A conductive fill material is deposited on the barrier layer and/or the adhesion layer and fills the recesses. The conductive fill material may be deposited by an electro-chemical plating process, CVD, ALD, PVD, a combination thereof, or the like. Examples of conductive fill material include copper, a copper alloy, silver, gold, tungsten, ruthenium, cobalt, aluminum, nickel, a combination thereof, or the like. Excess portions of the conductive fill material, the adhesion layer, the barrier layer, and/or the liner, such as portions extending along top surfaces of the substrate 202 (e.g., during formation of the first vias 231) and/or the ILD 210 (e.g., during formation of the second vias 232), are removed by planarization processes, such as a chemical-mechanical polish (CMP), a grinding process, an etch-back process, or the like. Remaining portions of the respective barrier layers, the respective adhesion layers, and/or the respective conductive fill materials form the first vias 231 and the second vias 232.

The middle die 200 may contain either or both of the first vias 231 and the second vias 232. In some embodiments (not specifically illustrated), the first vias 231 and the second vias 232 are not formed, and the third vias 233 and/or the fourth vias 234 may be formed instead. Any combination of some or all of the four types of conductive vias may be formed in the middle die 200.

As discussed above, the third vias 233 are a type of conductive via that may be subsequently formed through the back-side of the substrate 202 and connect to features referred to as buried contacts 230. In such embodiments, the buried contacts 230 may be formed along the substrate 202 before deposition of the ILD 210. In addition, the buried contacts 230 may be formed before or during formation of the devices 204. For example, recesses may be etched into the substrate 202 and filled with conductive material. In some embodiments, the conductive material includes one or more layers, such as a barrier layer and a conductive fill material. The barrier layer may be titanium, titanium nitride, tantalum, tantalum nitride, tungsten nitride, ruthenium, rhodium, platinum, other noble metals, other refractory metals, their nitrides, combinations of these, or the like. In addition, the conductive fill material may be tungsten, cobalt, ruthenium, rhodium, alloys thereof, or a combination thereof.

Still referring to FIG. 2A, the ILD 210 is formed on the front-side of the substrate 202. The ILD 210 surrounds and may cover the devices 204 as well as the buried contact 230 and the first via 231 (if present). The ILD 210 may include one or more dielectric layers formed of materials such as phosphosilicate glass (PSG), boro-silicate glass (BSG), boron-doped phosphosilicate glass (BPSG), un-doped silicate glass (USG), or the like.

Conductive plugs 212 may be formed extending through the ILD 210. The conductive plugs 212 may be electrically and physically coupled to the devices 204 as well as to the first via 231 and the buried contact 230 (if present). In embodiments in which the devices 204 are transistors, the conductive plugs 212 may be coupled to gates and/or source/drain regions of the transistors. The conductive plugs 212 may be formed of tungsten, cobalt, nickel, copper, silver, gold, aluminum, the like, or combinations thereof.

In FIG. 2B, an interconnect structure 220 is formed over the substrate 202 and the ILD 210 and the devices 204. In some embodiments (not specifically illustrated), the second vias 232 may be formed during formation of the interconnect structure 220 and be connected to either a lower portion or an upper portion of the interconnect structure 220.

The interconnect structure 220 may be formed similarly as described above in connection with the interconnect structure 120. For example, the interconnect structure 220 is formed on the ILD 210 and connected to the conductive plugs 212 and to the second vias (if present). The interconnect structure 220 interconnects the devices 204 to form integrated circuits. In some embodiments, the interconnect structure 220 may be formed of metallization patterns in dielectric layers on the ILD 210. The metallization patterns include metal lines and vias formed in one or more low-k dielectric layers. The metallization patterns of the interconnect structure 220 are electrically coupled to the devices 204, to the buried contacts 230, and to the first vias 231 by the conductive plugs 212, electrically connected to the second vias 232.

In FIG. 2C, third vias 233 and/or fourth vias 234 may be formed through the back-side of the substrate 202, in accordance with some embodiments. As discussed above, the third vias 233 are connected to the buried contacts 230, and the fourth vias 234 are connected to the devices 204 (e.g., gates and/or source/drain regions of the transistors).

Before forming the third vias 233 and the fourth vias 234, a carrier substrate 250 is attached to the interconnect structure 220, and a thinning process is performed on the back-side of the substrate 202. In some embodiments, the carrier substrate 250 may be attached using, for example, an adhesive layer 252 or other type of dielectric layer, which facilitates bonding of the carrier substrate 250 to the interconnect structure 220. As illustrated, a topmost dielectric layer (not separately labeled) of the interconnect structure 220 may be disposed over a topmost metallization layer of the interconnect structure 220, which improves attachment of the carrier substrate 250 using dielectric-to-dielectric bonding of this dielectric layer with the adhesive layer 252.

Following attachment of the carrier substrate 250, a thinning process is performed on the back-side of the substrate 202 which may expose the first vias 231 and the second vias 232. The substrate 202 may be thinned using may be a CMP, a grinding process, an etch-back process, a lapping process, or a polishing process.

After thinning the back-side of the substrate 202, the third vias 233 and the fourth vias 234 may be formed through the back-side of the substrate 202 and similarly as described above in connection with the first vias 231 and/or the second vias 232. The third vias 233 and the fourth vias 234 may be formed similarly and simultaneously, unless otherwise specified. As discussed above, it should be noted that the third vias 233 are formed to connect to the buried contacts, and the fourth vias 234 are formed to connect to the devices 204 (e.g., gates and/or source/drain regions).

For example, the third vias 233 and the fourth vias 234 are formed by forming recesses in the thinned back-side of the substrate 202. The respective recesses may be formed by etching, milling, laser techniques, a combination thereof, or the like. A liner (not specifically illustrated) may be formed in the recesses, such as by thermal oxidation, atomic layer deposition (ALD), chemical vapor deposition (CVD), or the like. The liner may be a dielectric material and include oxides, such as silicon oxide, silicon oxynitride, or the like. A barrier layer and/or an adhesion layer (not specifically illustrated) may then be conformally deposited in the recesses (e.g., along the liner), such as by CVD, ALD, physical vapor deposition (PVD), a combination thereof, or the like. The barrier layer and/or the adhesion layer may be formed of titanium, titanium nitride, tantalum, tantalum nitride, or the like. A conductive fill material is deposited on the barrier layer and/or the adhesion layer and fills the recesses. The conductive fill material may be deposited by an electro-chemical plating process, CVD, ALD, PVD, a combination thereof, or the like. Examples of conductive fill material include copper, a copper alloy, silver, gold, tungsten, ruthenium, cobalt, aluminum, nickel, a combination thereof, or the like. Excess portions of the conductive fill material, the adhesion layer, the barrier layer, and/or the liner, such as portions extending along top surfaces of the substrate 202 (e.g., during formation of the first vias 231) and/or the ILD 210 (e.g., during formation of the second vias 232), are removed by planarization processes, such as a chemical-mechanical polish (CMP), a grinding process, an etch-back process, or the like. In embodiments in which the first vias 231 and the second vias 232 remained covered by the back-side of the substrate 202 after the thinning process described above, these planarization processes may expose the first vias 231 and the second vias 232. Remaining portions of the respective barrier layers, the respective adhesion layers, and/or the respective conductive fill materials form the third vias 233 and the fourth vias 234.

FIG. 2D illustrates a closer view of region 201 labeled in FIG. 2C. The conductive vias are illustrated with conductive fill materials and liner layers, such as the respective barrier layers and/or adhesive layers discussed above in connection with forming them. For example, the first via 231 is shown with liner layer(s) 231A and conductive fill material 231B. The second via 232 is shown with liner layer(s) 232A and conductive fill material 232B. The third via 233 is shown with liner layer(s) 233A and conductive fill material 233B. The fourth via 234 is shown with liner layer(s) 234A and conductive fill material 234B.

In some embodiments, the first vias 231 have an uppermost width (e.g., at the front-side surface of the substrate 202) that is equal to or less than an uppermost width of the second vias 232 (e.g., at the top surface of the ILD 210). Similarly, the first vias 231 may have a lowermost width that is equal to or less than a lowermost width of the second vias 232. In addition, the uppermost widths and the lowermost widths of the second vias 232 may be equal to or less than the analogous widths of the conductive vias 130 of the bottom wafer 100. In addition, the third vias 233 and the fourth vias 234 may have uppermost widths (e.g., at the buried contact 230 and the corresponding device 204, respectively) that are less than the lowermost widths of the first vias 231 and the second vias 232. Further, the third vias 233 and the fourth vias 234 may have lower widths (e.g., at the back-side surface of the substrate 202) that are less than the uppermost widths of the first vias 231 and the second vias 232.

In FIG. 2E, an interconnect structure 270 is formed over the back-side of the middle die 200, and metal pads 280 (e.g., aluminum pads), bond pad vias 284, and bond pads 286, to which external connections are made, are formed over the interconnect structure 270. The interconnect structure 270, metal pads 280, and other back-side features may be collectively referred to as a back-side power delivery network (BSPDN). The BSPDN allows for power and signal routing for the integrated circuit of the middle die 200 to be on either or both of the front-side and back-side of the middle die 200, which achieves several advantages. For example, the footprint of the middle die 200 (or subsequently formed semiconductor package that includes the middle die 200) may decrease by up to 28-30%, a surface density of the bond pads 286 and interconnect structures may increase by up to 1500%, a signal path with a directly connected die may decrease by 10.8%, overall voltage drop may decrease with shorter distances (e.g., from external power to the devices 204) by an average of up to 60%, and a maximum voltage drop may decrease by up to 20%. As a result, performance of the middle die 200 may improve by up to 15%. The interconnect structure 270 may be formed similarly as described above in connection with the interconnect structures 120, 220. The metal pads 280, the bond pad vias 284, and the bond pads 286 may be formed similarly as described above in connection with the metal pads 140, the bond pad vias 144, and the bond pads 146, respectively.

The interconnect structure 270 is formed over the back-side of the substrate 202 and connected to the conductive vias or TSVs (e.g., the first vias 231, the second vias 232, the third vias 233, and/or the fourth vias 234). The interconnect structure 270 interconnects the devices 204 to become part of the integrated circuit. In some embodiments, the interconnect structure 270 may be formed of metallization patterns embedded in dielectric layers. The metallization patterns include metal lines and vias formed in one or more low-k dielectric layers. The metallization patterns of the interconnect structure 270 are electrically coupled to the devices 204 by the conductive vias or TSVs, and are electrically connected to the interconnect structure 220.

In accordance with some embodiments, the metal pads 280 (e.g., aluminum pads), the bond pad vias 284, and the bond pads 286, to which external connections are made, are formed over the interconnect structure 270 on the back-side of the middle die 200. As illustrated, the metal pads 280 are disposed over and electrically connected to the metallization layers of the interconnect structure 270. The metal pads 280 may be within one or more dielectric layers 281 and comprise a metal, such as aluminum, copper, or the like. For example, the dielectric layers 281 may include a silicon oxide and/or a silicon nitride, such as silicon oxynitride (SiON), silicon carbide (SiC), or any suitable material. The metal pads 280 may be considered part of the interconnect structure 270. In some embodiments (not specifically illustrated), solder regions (e.g., solder balls or solder bumps) may be disposed on the metal pads 280. The solder regions may be used to perform chip probe testing on the integrated circuits of the middle dies 200. Chip probe testing may be performed on the middle die 200 to ascertain whether the middle die 200 is a known good die (KGD). Thus, only middle dies 200, which are KGDs, undergo subsequent processing and are packaged. Dies that fail the chip probe testing, are not packaged. After testing, the solder regions may be removed in subsequent processing steps.

In accordance with some embodiments, the bond pad vias 284 and the bond pads 286 are formed over the metal pads 280 and the interconnect structure 270. The bond pad vias 284 and the bond pads 286 may be formed using single or dual damascene processes similarly as described above in connection with the bond pad vias 144 and the bond pads 146 of the bottom wafer. For example, a dielectric bond layer 282 may be formed over the metal pads 280, and the dielectric bond layer 282 and the dielectric layers 281 may be etched to form recesses. The recesses may then be filled to form the bond pad vias 284 and the bond pads 286.

For example, the dielectric bond layer 282 may be formed over the interconnect structure 270 and the metal pads 280. The dielectric bond layer 282 may be one or more dielectric layers that include an oxide such as silicon oxide, a nitride such as silicon nitride, or combinations thereof, and may be formed using CVD, ALD, the like, or a suitable method. In accordance with some embodiments, the dielectric bond layer 282 includes a silicon oxide layer. The dielectric bond layer 282 and the underlying dielectric layers 281 are etched to form recesses that expose the metal pads 280. In embodiments that use a dual damascene process, the recesses may be formed using multiple etch processes, and the bond pad vias 284 and the bond pads 286 may be simultaneously formed. For example, after forming the recesses a conductive liner and a conductive material may be deposited in the recesses and over the dielectric bond layer 282, and a planarization process may be performed to remove excess portions of the conductive material and the conductive liner from a top surface of the dielectric bond layer 282. In some embodiments (not specifically illustrated), the bond pad vias 284 may be formed through the dielectrics layer 281, and the bond pads 286 may be subsequently formed through the dielectric bond layer 282.

In some embodiments (not specifically illustrated), the bond pads 286 may be formed after the bond pad vias 284, and the bond pads 286 may be microbumps, ball grid array (BGA) connectors, solder balls, metal pillars, controlled collapse chip connection (C4) bumps, electroless nickel-electroless palladium-immersion gold technique (ENEPIG) formed bumps, or the like. The bond pads 286 may include a conductive material such as solder, copper, aluminum, gold, nickel, silver, palladium, tin, the like, or a combination thereof. In some embodiments, the bond pads 286 are formed by initially forming a layer of solder through evaporation, electroplating, printing, solder transfer, ball placement, or the like. Once a layer of solder has been formed on the structure, a reflow may be performed in order to shape the material into the desired bump shapes. In addition, the dielectric bond layer 282 may be a polymer such as PBO, polyimide, BCB, or the like; a nitride such as silicon nitride or the like; an oxide such as silicon oxide, PSG, BSG, BPSG, or the like; the like, or a combination thereof. The dielectric bond layer 282 may be formed by spin coating, lamination, CVD, or the like. Initially, the dielectric bond layer 282 may bury the bond pads 286, such that a topmost surface of the dielectric bond layer 282 is above topmost surfaces of the bond pads 286. In some embodiments, solder regions may be formed on the bond pads 286, and the dielectric bond layer 282 may bury the solder regions. In some embodiments, the bond pads 286 are exposed through or protrude above the dielectric bond layer 282 during formation of the middle die 200. In some embodiments, the bond pads 286 remain buried and are exposed during a subsequent process for packaging the middle die 200. Exposing the bond pads 286 may include removing any solder regions that may be present on the bond pads 286.

FIGS. 3A-3B illustrate cross-sectional views of forming a top die 300, in accordance with some embodiments. The top die 300 includes an integrated circuit die formed in a wafer, which may include different device regions that are singulated in subsequent steps to form a plurality of singulated integrated circuit dies. The wafer including the top die 300 may be processed according to applicable manufacturing processes to form singulated top dies 300. The top die 300 may be formed similarly as described above in connection with analogous features of the bottom wafer 100 or the middle die 200 unless otherwise specified. The top die 300 may be a logic die (e.g., a CPU, a GPU, an SoC, an AP, a microcontroller, or the like); a memory die (e.g., a DRAM die, an SRAM die, or the like); a power management die (e.g., a PMIC die); an RF die; a sensor die; a MEMS die; a signal processing die (e.g., a DSP die); a front-end die (e.g., an AFE die); or a combination thereof.

In FIG. 3A, the devices 304 are formed in a front-side of the substrate 302. For example, the substrate 302 may include a semiconductor substrate, such as silicon, doped or un-doped, or an active layer of a semiconductor-on-insulator (SOI) substrate. The semiconductor substrate may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may be used. The substrate 302 has an active surface (e.g., the surface facing upwards in FIG. 3A on which the devices 304 are formed), which may be referred to as the front-side, and an inactive surface (e.g., the surface facing downwards in FIG. 3A), which may be referred to as the back-side. The devices 304 (represented by a transistor) may be formed at the front-side of the substrate 302. The devices 304 may be active devices (e.g., transistors, diodes, or the like), capacitors, resistors, or the like. An ILD 310 is also formed on the front-side of the substrate 202.

In accordance with some embodiments, the ILD 310 is on the front-side of the substrate 302. The ILD 310 surrounds and may cover the devices 304. The ILD 210 may include one or more dielectric layers formed of materials such as phosphosilicate glass (PSG), boro-silicate glass (BSG), boron-doped phosphosilicate glass (BPSG), un-doped silicate glass (USG), or the like.

Conductive plugs 312 may be formed extending through the ILD 310. The conductive plugs 312 may be electrically and physically coupled to the devices 304. In embodiments in which the devices 304 are transistors, the conductive plugs 312 may be coupled to gates and/or source/drain regions of the transistors. The conductive plugs 312 may be formed of tungsten, cobalt, nickel, copper, silver, gold, aluminum, the like, or combinations thereof.

In FIG. 3B, an interconnect structure 320 is formed over the ILD 310 of the top die 300, and metal pads 340 (e.g., aluminum pads), bond pad vias 344, and bond pads 346, to which external connections are made, are formed over the interconnect structure 320. The interconnect structure 320 may be formed similarly as described above in connection with the interconnect structures 120, 220, 270. The metal pads 340, the bond pad vias 344, and the bond pads 346 may be formed similarly as described above in connection with the metal pads 140, 280, the bond pad vias 144, 284, and the bond pads 146, 286, respectively.

The interconnect structure 320 is formed over the front-side of the substrate 302 and connected to the conductive plugs 312. The interconnect structure 320 interconnects the devices 304 to become part of the integrated circuit. In some embodiments, the interconnect structure 320 may be formed of metallization patterns embedded in dielectric layers. The metallization patterns include metal lines and vias formed in one or more low-k dielectric layers. The metallization patterns of the interconnect structure 320 are electrically coupled to the devices 304 by the conductive plugs 312.

In accordance with some embodiments, the metal pads 340 (e.g., aluminum pads), the bond pad vias 344, and the bond pads 346, to which external connections are made, are formed over the interconnect structure 320. As illustrated, the metal pads 340 are disposed over and electrically connected to the metallization layers of the interconnect structure 320. The metal pads 340 may be within one or more dielectric layers 341 and comprise a metal, such as aluminum, copper, or the like. For example, the dielectric layers 341 may include a silicon oxide and/or a silicon nitride, such as silicon oxynitride (SiON), silicon carbide (SiC), or any suitable material. The metal pads 340 may be considered part of the interconnect structure 320. In some embodiments (not specifically illustrated), solder regions (e.g., solder balls or solder bumps) may be disposed on the metal pads 340. The solder regions may be used to perform chip probe testing on the integrated circuits of the top dies 300. Chip probe testing may be performed on the top die 300 to ascertain whether the top die 300 is a known good die (KGD). Thus, only top dies 300, which are KGDs, undergo subsequent processing and are packaged. Dies that fail the chip probe testing, are not packaged. After testing, the solder regions may be removed in subsequent processing steps.

In accordance with some embodiments, the bond pad vias 344 and the bond pads 346 are formed over the metal pads 340 and the interconnect structure 320. The bond pad vias 344 and the bond pads 346 may be formed using single or dual damascene processes similarly as described above in connection with the bond pad vias 144, 284 and the bond pads 146, 286 of the bottom wafer 100 and the middle die 200, respectively. For example, a dielectric bond layer 342 may be formed over the metal pads 340, and the dielectric bond layer 342 and the dielectric layers 341 may be etched to form recesses. The recesses may then be filled to form the bond pad vias 344 and the bond pads 346.

For example, the dielectric bond layer 342 may be formed over the interconnect structure 320 and the metal pads 340. The dielectric bond layer 342 may be one or more dielectric layers that include an oxide such as silicon oxide, a nitride such as silicon nitride, or combinations thereof, and may be formed using CVD, ALD, the like, or a suitable method. In accordance with some embodiments, the dielectric bond layer 342 includes a silicon oxide layer. The dielectric bond layer 342 and the one or more underlying dielectric layers 341 are etched to form recesses that expose the metal pads 340. In embodiments that use a dual damascene process, the recesses may be formed using multiple etch processes, and the bond pad vias 344 and the bond pads 346 may be simultaneously formed. For example, after forming the recesses, a conductive liner and a conductive material may be deposited in the recesses and over the dielectric bond layer 342, and a planarization process may be performed to remove excess portions of the conductive material and the conductive liner from a top surface of the dielectric bond layer 342. In some embodiments (not specifically illustrated), the bond pad vias 344 may be formed through the dielectrics layer 341, and the bond pads 346 may be subsequently formed through the dielectric bond layer 342.

In some embodiments (not specifically illustrated), the bond pads 346 may be formed after the bond pad vias 344, and the bond pads 346 may be microbumps, ball grid array (BGA) connectors, solder balls, metal pillars, controlled collapse chip connection (C4) bumps, electroless nickel-electroless palladium-immersion gold technique (ENEPIG) formed bumps, or the like. The bond pads 346 may include a conductive material such as solder, copper, aluminum, gold, nickel, silver, palladium, tin, the like, or a combination thereof. In some embodiments, the bond pads 346 are formed by initially forming a layer of solder through evaporation, electroplating, printing, solder transfer, ball placement, or the like. Once a layer of solder has been formed on the structure, a reflow may be performed in order to shape the material into the desired bump shapes. In addition, the dielectric bond layer 342 may be a polymer such as PBO, polyimide, BCB, or the like; a nitride such as silicon nitride or the like; an oxide such as silicon oxide, PSG, BSG, BPSG, or the like; the like, or a combination thereof. The dielectric bond layer 342 may be formed by spin coating, lamination, CVD, or the like. Initially, the dielectric bond layer 342 may bury the bond pads 346, such that a topmost surface of the dielectric bond layer 342 is above topmost surfaces of the bond pads 346. In some embodiments, solder regions may be formed on the bond pads 346, and the dielectric bond layer 342 may bury the solder regions. In some embodiments, the bond pads 346 are exposed through or protrude above the dielectric bond layer 342 during formation of the top die 300. In some embodiments, the bond pads 346 remain buried and are exposed during a subsequent process for packaging the top die 300. Exposing the bond pads 346 may include removing any solder regions that may be present on the bond pads 346.

In some embodiments (not specifically illustrated), conductive vias may be formed extending from the front-side through to the back-side of the substrate 302 of the top die 300. For example, the conductive vias may be formed similarly as some or all of the conductive vias 130 of the bottom wafer 100 and the first vias 231, second vias 232, third vias 233 (e.g., including the buried contacts 230), and the fourth vias 234 of the middle die 200. In such embodiments, additional conductive features may be formed over the back-side of the top die 300, such as an interconnect structure, pads, bond pad vias, and bond pads, similarly as described above in connection with the top die 300, the middle die 200, and/or the bottom wafer 100.

FIGS. 4-8 illustrate cross-sectional views of forming a semiconductor package using the above-described components, in accordance with some embodiments. In the illustrated embodiment, one or more middle dies 200 are attached to a bottom wafer 100, the middle dies 200 are subsequently processed, one or more top dies 300 are attached to the middle dies 200, and further processing is performed on the structure to form a multi-level semiconductor package. Note that the semiconductor package is illustrated showing one integrated circuit die of the bottom wafer 100, one middle die 200, and one top die 300, although any suitable number of the middle dies 200 and the top dies 300 may be included in the semiconductor package.

In FIG. 4, an exemplary middle die 200 (see FIG. 2E) is attached to an exemplary bottom wafer 100 (see FIG. 1C). In addition, the carrier substrate 250 is removed, and an encapsulant 402 is formed around the middle die 200. As illustrated, the back-side of the middle die 200 may be facing the front-side of the bottom wafer 100 in a face-to-back attachment. The formation of the BSPDN (e.g., the interconnect structure 270 and others features) on the middle die 200 allows for this attachment to be analogous to a face-to-face attachment.

In accordance with some embodiments, the middle die 200 may be attached to a package region of the bottom wafer 100 with the back-side of the middle die 200 facing the front-side of the bottom wafer 100. It should be noted that other middle die 200 may be attached to other package regions of the bottom wafer 100 (e.g., at the wafer level) that may not be specifically illustrated. For example, fusion bonding, dielectric bonding, metal bonding, the like, or combinations thereof, such as dielectric-to-dielectric and metal-to-metal bonding, may be used to directly bond the dielectric bond layer 282 and bond pads 286 of the middle die 200 to the dielectric bond layer 142 and the bond pads 146, respectively, without the use of adhesive or solder.

As noted above, the bonding of the middle die 200 to the bottom wafer 100 may be achieved through a combination of metal-to-metal direct bonding (between the bond pads 286 of the middle die 200 and the bond pads 146 of the bottom wafer 100) and dielectric-to-dielectric bonding (such as Si-O-Si and/or Si-N-Si bonding between the dielectric bond layer 282 and the dielectric bond layer 142) are formed.

For example, the dielectric bond layer 282 of the middle die 200 is bonded to the dielectric bond layer 142 of the bottom wafer 100 through dielectric-to-dielectric bonding without using any adhesive material (e.g., die attach film). Similarly, the bond pads 286 are bonded to the bond pads 146 through metal-to-metal bonding, without using any eutectic material (e.g., solder). The bonding may include a pre-bonding and an annealing. During the pre-bonding, a small pressing force may be applied to press the middle die 200 against the bottom wafer 100. The pre-bonding is performed at a low temperature, such as room temperature (e.g., ranging from 15 °C to 30 °C), and after the pre-bonding, the dielectric bond layer 282 and the dielectric bond layer 142 are bonded to each other. The bonding strength is then improved in a subsequent annealing step, in which the structure is annealed at a high temperature, such as a temperature ranging from 100 °C to 450 °C. After the annealing, bonds (e.g., fusion bonds and/or chemical bonds) are formed between the dielectric bond layer 282 and the dielectric bond layer 142. For example, the bonds can be covalent bonds between the material of the dielectric bond layer 282 and the material of the dielectric bond layer 142.

As illustrated, the bond pads 286 of the middle die 200 and the bond pads 146 of the bottom wafer 100 are aligned and electrically connected to each other. The bond pads 286 and the bond pads 146 may be in physical contact during the pre-bonding, or may expand to be brought into physical contact during the annealing. Further, during the annealing, the material of the bond pads 286 (e.g., copper) and the material of the bond pads 146 (e.g., copper) intermingle, so that metal-to-metal bonds are also formed. Hence, the resulting bonds between the middle die 200 and the bottom wafer 100 include a combination of both dielectric-to-dielectric bonds and metal-to-metal bonds.

Still referring to FIG. 4, the carrier substrate 250 is removed from the middle die 200. Some or all of the adhesive layer 252 (if present) may remain over the interconnect structure 220. In some embodiments, a debonding process may be performed by projecting a light such as a laser light or an ultraviolet (UV) light on the adhesive layer 252 so that the adhesive layer 252 decomposes under the heat of the light, thereby permitting removal of the carrier substrate 250. In some embodiments, the carrier substrate 250 and the adhesive layer 252 (if present) are removed by a lapping process. It should be noted that the carrier substrate 250 may be removed using any suitable method.

In accordance with some embodiments, an encapsulant 402 is formed on and around the various components, and a thinning process may be performed to remove excess encapsulant 402 disposed over the interconnect structure 220. After formation, the encapsulant 402 encapsulates upper surfaces and sidewalls of the middle die 200. The encapsulant 402 is further formed in gap regions between adjacent ones of the middle die 200. The encapsulant 402 may be a molding compound, an epoxy, a resin, or the like. The encapsulant 402 may be applied by compression molding, transfer molding, or the like, and may be formed over the structure such that the middle die 200 is buried or covered. As additional examples, the encapsulant 402 may comprise a nitride (e.g., silicon nitride) and/or an oxide (e.g., silicon oxide) and may be deposited using spin coating, FCVD, PECVD, LPCVD, ALD, or any suitable process. The encapsulant 402 may be applied in liquid or semi-liquid form and then subsequently cured. The encapsulant 402 is optionally thinned to expose the middle die 200. The thinning process may be a grinding process, a CMP, an etch-back, combinations thereof, or the like and may remove portions of the middle die 200 (e.g., portions or all of the adhesive layer 252, if present). After the thinning process, the top surfaces of the encapsulant 402 and the middle die 200 are coplanar (within process variations). The thinning is performed until a desired amount of the encapsulant 402 and the middle die 200 has been removed. In accordance with some embodiments, the thinning may be stopped without exposing the interconnect structure 220 of the middle die 200.

In some embodiments (not specifically illustrated), a liner layer may be formed over and between the middle die 200 before forming the encapsulant 402. The liner layer may be a conformal layer extending along the upper surfaces and the sidewalls of the middle die 200 as well as along upper surfaces of the dielectric bond layer 142 and may serve as a moisture stop layer. The liner layer is formed of a dielectric material that has good adhesion to the sidewalls of the middle die 200. For example, the liner layer may be formed of an extra low-k (ELK) material, including a nitride (e.g., silicon nitride) and/or an oxide (e.g., silicon oxide). Deposition of the liner layer may include a conformal deposition process such as ALD, CVD, or any suitable process. The encapsulant 402 may then be formed over the liner layer as described above. The thinning process may then remove portions of the liner layer and the encapsulant 402 from the top surfaces (e.g., the back sides) of the middle die 200.

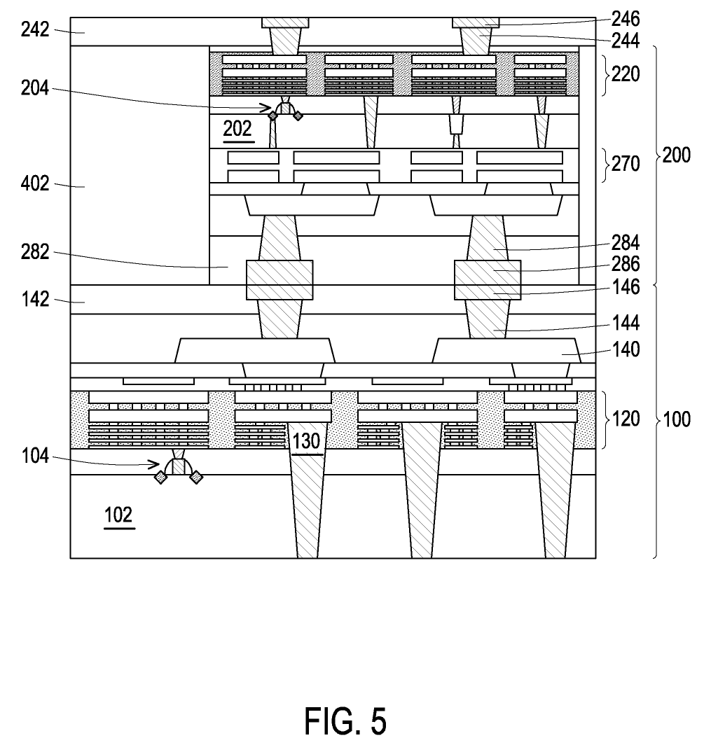

In FIG. 5, bond pad vias 244 and bond pads 246 are formed over and electrically connected to the interconnect structure 220 of the middle die 200. The bond pad vias 244 and the bond pads 246 may be formed similarly as described above in connection with other features of the same name. For example, a dielectric bond layer 242 may be deposited over the middle die 200 and the encapsulant 402. Recesses may be formed in the dielectric bond layer 242 and any other underlying dielectric layers disposed over the interconnect structure 220 in order to expose the interconnect structure 220. The bond pad vias 244 and the bond pads 246 may be formed sequentially in single damascene processes or simultaneously in a dual damascene process.

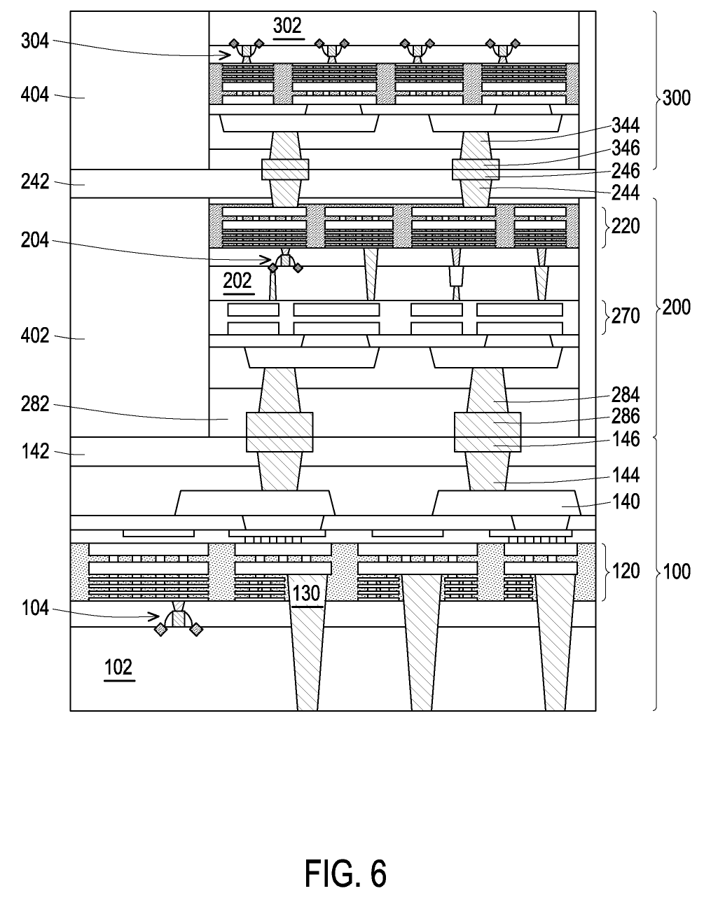

In FIG. 6, an exemplary top die 300 (see FIG. 3B) is attached to the middle die 200, and an encapsulant 404 is formed around the top die 300. In accordance with some embodiments, the top die 300 may be attached to the middle die 200 with the front-side of the top die 300 facing the front-side of the middle die 200. It should be noted that other top dies 300 may be attached to the same or others of the middle die 200 that may not be specifically illustrated. For example, fusion bonding, dielectric bonding, metal bonding, the like, or combinations thereof, such as dielectric-to-dielectric and metal-to-metal bonding, may be used to directly bond the dielectric bond layer 342 and bond pads 346 of the top die 300 to the dielectric bond layer 242 and the bond pads 246, respectively, without the use of adhesive or solder.

In some embodiments, the top die 300 is attached to the middle die 200 similarly as described above in connection with attaching the middle die 200 to the bottom wafer 100. For example, the bonding of the top die 300 to the middle die 200 may be achieved through a combination of metal-to-metal direct bonding (between the bond pads 346 of the top die 300 and the bond pads 246 of the middle die 200) and dielectric-to-dielectric bonding (such as Si-O-Si and/or Si-N-Si bonding between the dielectric bond layer 342 and the dielectric bond layer 242) are formed.

After attaching the top die 300, the encapsulant 404 is formed on and around the various components, and a thinning process may be performed to remove excess encapsulant 404 disposed over the substrate 302 of the top die 300. After formation, the encapsulant 404 encapsulates upper surfaces and sidewalls of the top die 300. The encapsulant 404 is further formed in gap regions between adjacent ones of the top die 300. The encapsulant 404 may be a molding compound, an epoxy, a resin, or the like. The encapsulant 404 may be applied by compression molding, transfer molding, or the like, and may be formed over the structure such that the top die 300 is buried or covered. As additional examples, the encapsulant 404 may comprise a nitride (e.g., silicon nitride) and/or an oxide (e.g., silicon oxide) and may be deposited using spin coating, FCVD, PECVD, LPCVD, ALD, or any suitable process. The encapsulant 404 may be applied in liquid or semi-liquid form and then subsequently cured. The encapsulant 404 is optionally thinned to expose the top die 300. The thinning process may be a grinding process, a CMP, an etch-back, combinations thereof, or the like and may remove portions of the top die 300 (e.g., portions or all of the adhesive layer 252, if present). After the thinning process, the top surfaces of the encapsulant 404 and the top die 300 (e.g., the substrate 302) are coplanar (within process variations). The thinning is performed until a desired amount of the encapsulant 404 and the top die 300 has been removed, such as reducing the semiconductor package to a desired thickness.

In some embodiments (not specifically illustrated), a liner layer may be formed over and between the top die 300 before forming the encapsulant 404. The liner layer may be a conformal layer extending along the upper surfaces and the sidewalls of the top die 300 as well as along upper surfaces of the dielectric bond layer 242 and may serve as a moisture stop layer. The liner layer is formed of a dielectric material that has good adhesion to the sidewalls of the top die 300. For example, the liner layer may be formed of an extra low-k (ELK) material, including a nitride (e.g., silicon nitride) and/or an oxide (e.g., silicon oxide). Deposition of the liner layer may include a conformal deposition process such as ALD, CVD, or any suitable process. The encapsulant 404 may then be formed over the liner layer as described above. The thinning process may then remove portions of the liner layer and the encapsulant 404 from the top surfaces (e.g., the back sides) of the top die 300.

In FIG. 7, a carrier substrate 410 is attached to the top die 300, and a thinning process is performed on the substrate 102 of the bottom wafer 100 to expose the conductive vias 130. In some embodiments, the carrier substrate 410 may be attached using, for example, an adhesive layer 412 or other type of dielectric layer, which facilitates bonding of the carrier substrate 410 to the top die 300. Following attachment of the carrier substrate 250, a thinning process is performed on the substrate 102 of the bottom wafer 100 which may expose the conductive vias 130. The substrate 102 may be thinned using may be a CMP, a grinding process, an etch-back process, a lapping process, or a polishing process.

In FIG. 8, the back-side of the bottom wafer 100 may be processed to facilitate subsequent external electrical connection and/or attachment of the semiconductor package into an electronic device (not specifically illustrated). In accordance with some embodiments, the back-side processing may include forming an interconnect structure 170 and metal pads 180 over the bottom wafer 100 (e.g., a back-side power delivery network similar to and achieving similar advantages as the middle die 200). For example, the interconnect structure 170 is formed over the back-side of the substrate 102, and metal pads 180 (e.g., aluminum pads), to which external connections are made, are formed over the interconnect structure 170. The interconnect structure 170 may be formed similarly as described above in connection with the interconnect structures 120, 220, 270, 320. The metal pads 180 may be formed similarly as described above in connection with the metal pads 140, 240, 280, 340.

The interconnect structure 170 is formed over the back-side of the substrate 102 and connected to the conductive vias 130 (e.g., the TSVs). The interconnect structure 170 interconnects the devices 104 to become part of the integrated circuits within the bottom wafer 100. In some embodiments, the interconnect structure 170 may be formed of metallization patterns embedded in dielectric layers. The metallization patterns include metal lines and vias formed in one or more low-k dielectric layers. The metallization patterns of the interconnect structure 170 are electrically coupled to the devices 104 by the conductive vias 130, and are electrically connected to the interconnect structure 120 of the front-side of the substrate 102.

As illustrated, the metal pads 180 are disposed over and electrically connected to the metallization layers of the interconnect structure 170. The metal pads 180 may be within one or more dielectric layers 181 and comprise a metal, such as aluminum, copper, or the like. For example, the dielectric layers 181 may include a silicon oxide and/or a silicon nitride, such as silicon oxynitride (SiON), silicon carbide (SiC), or any suitable material. The metal pads 180 may be considered part of the interconnect structure 170. In some embodiments (not specifically illustrated), the metal pads 180 may be formed over the back-side of the substrate 102 and connected to the conductive vias 130 without forming the interconnect structure 170.

In some embodiments (not specifically illustrated), some of the metal pads 180 may be exposed to perform, for example, electrical and thermal testing of the semiconductor package. For example, a probe may be used to contact these metal pads 180 directly or solder regions (e.g., solder balls or solder bumps) may be disposed on the metal pads 180 for the probe to make direct contact with.

Although not specifically illustrated, subsequent processing of the semiconductor package may be performed, such as forming external connectors over and electrically connected to the metal pads 180 and performing a singulation to separate the structure into individual semiconductor packages. The electrical and thermal testing of the semiconductor package described above may be performed after forming the external connectors. Further, some embodiments (not specifically illustrated) may include a BSPDN on the top die 300. In such embodiments, external connectors may also or alternatively be formed on the top die 300.

FIGS. 9-12 illustrate various layouts of additional semiconductor packages that may be formed with the components described in FIGS. 1A-3B. These semiconductor packages may be assembled using applicable processes described in FIGS. 4-8. As further illustrated, external connectors 420 have been formed over the interconnect structure 170 of the bottom wafer 100 using processes described above in connection with the back-side processing of the bottom wafer 100. With respect to semiconductor packages having a plurality of middles dies 200 and/or a plurality of top dies 300, it should be noted that each of the middle dies 200 and/or the top dies 300 may be the same integrated circuit die (e.g., formed simultaneously within a same wafer), the same type of integrated circuit die, different integrated circuit dies of a same type, or different types of integrated circuit dies. All relevant combinations are fully intended to be within the scope of the disclosure.

FIG. 9 illustrates a semiconductor package in which two or more middle dies 200 and two or more top dies 300 are attached to a single device region of a bottom wafer 100. As such, after singulation, each semiconductor package will include two or more middle dies 200 and two or more top dies 300. Although two middle dies 200 and two top dies 300 are illustrated, any suitable number may be included in each semiconductor package. In addition, the number of middle dies 200 may differ from the number of top dies 300. Note that each of the top dies 300 is only directly electrically connected to a respective underlying middle die 200, and the top dies 300 are indirectly electrically connected to one another.

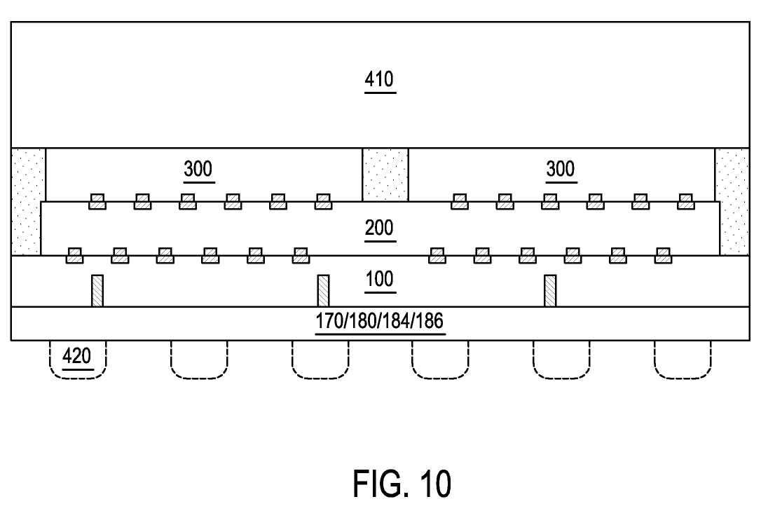

FIG. 10 illustrates a semiconductor package in which one middle die 200 and two or more top dies 300 are attached to a single device region of a bottom wafer 100. As such, after singulation, each semiconductor package will include one middle die 200 and two or more top dies 300. Although two top dies 300 are illustrated, any suitable number of top dies 300 may be included in each semiconductor package. Note that each of the top dies 300 is directly electrically connected to the middle die 200.

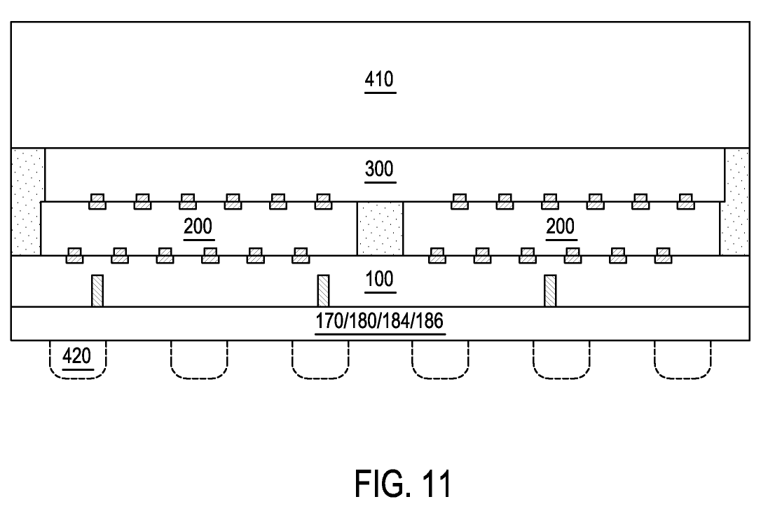

FIG. 11 illustrates a semiconductor package in which two or more middle dies 200 and one top die 300 are attached to a single device region of a bottom wafer 100. As such, after singulation, each semiconductor package will include two or more middle dies 200 and one top die 300. Although two middle dies 200 are illustrated, any suitable number of middle dies 200 may be included in each semiconductor package. Note that each of the middle dies 200 is directly electrically connected to the bottom wafer 100 and directly electrically connected to the top die 300 (e.g., electrically interposed between the bottom wafer 100 and the top die 300). As such, the middle dies 200 are indirectly electrically connected to one another.

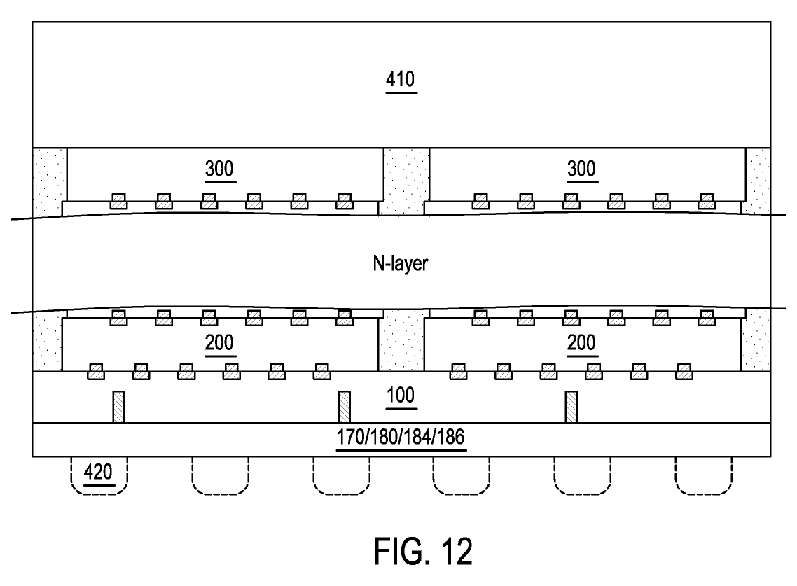

FIG. 12 illustrates a semiconductor package in which two or more tiers or layers (e.g., an N-layer stack) of middle dies 200 are attached to a single device region of a bottom wafer 100. Although illustrated with each of the top dies 300 being directly electrically connected to one corresponding middle die 200 in the Nth layer of the N-layer stack, the layout of the Nth layer middle dies 200 and the top dies 300 may follow any of the layouts described above in connection with FIGS. 8-11. In addition, the layout of the N-layer stack of middle dies 200 may be analogous to any of the layouts described above in connection with FIGS. 8-11.

Embodiments may achieve various advantages. As discussed above, formation of the various integrated circuit dies allows for many different layouts for assembling a semiconductor package. In particular, the semiconductor package may have three or more tiers of integrated circuit dies, including the integrated circuit within the bottom wafer 100, one or more middle dies 200, and one or more top dies 300. In accordance with the various embodiments, the semiconductor package may be assembled to have more stacking versatility, a smaller footprint, faster and more reliable electrical connectivity between the integrated circuit dies, higher interconnect density along with improved performance.

In an embodiment, a method includes: attaching a front-side of a first die to a front-side of a wafer, the first bond pad being along a back-side of the first die, the wafer comprising a substrate and a transistor along the substrate, the transistor facing the front-side of the wafer, the first die comprising: a first bond pad along the back-side of the first die; a first back-side interconnect structure adjacent and electrically connected to the first bond pad; a first front-side interconnect structure adjacent and electrically connected to the first back-side interconnect structure; a first semiconductor substrate interposed between the first back-side interconnect structure and the first front-side interconnect structure; and a first transistor along the first semiconductor substrate, the first transistor facing the front-side of the first die; forming a second bond pad over the first front-side interconnect structure; and attaching a second front-side of a second die to the second bond pad of the first die, the second die comprising a second semiconductor substrate and a second transistor, the second transistor facing the front-side of the second die. In another embodiment, the first die comprises a first type of conductive via and a second type of conductive via extending through the first semiconductor substrate, wherein a width of the first type of conductive via decreases in a direction from the front-side of the first die to the back-side of the first die, and wherein a width of the second type of conductive via decreases in a direction from the back-side of the first die to the front-side of the first die. In another embodiment, the first type of conductive via comprises a first via and a second via, wherein the first via extends from a front-side of the first semiconductor substrate to a back-side of the first semiconductor substrate, and wherein the second via extends from the first front-side interconnect structure to the back-side of the first semiconductor substrate. In another embodiment, the second type of conductive via comprises a third via and a fourth via, and wherein the third via extends from the back-side of the first semiconductor substrate and is electrically coupled to a buried contact embedded in the front-side of the first semiconductor substrate. In another embodiment, the fourth via extends from the back-side of the first semiconductor substrate and is electrically coupled to the first transistor. In another embodiment, the first type of conductive via is wider than the second type of conductive via. In another embodiment, forming the second bond pad is after attaching the back-side of the first die to the front-side of the wafer. In another embodiment, the method further includes: attaching a carrier to a back-side of the second die; thinning the substrate along a back-side of the wafer; and forming a back-side interconnect structure on the back-side of the wafer.

In an embodiment, a method includes: forming a first die, forming the first die comprising: forming a first conductive via in a front-side of a substrate; forming a transistor comprising a gate electrode and a source/drain region over the front-side of the substrate; forming a first interconnect structure over the front-side of the substrate, the first interconnect structure being electrically connected to the gate electrode; forming a second conductive via in a back-side of the substrate, the second conductive via being connected to the source/drain region; and forming a second interconnect structure over the back-side of the substrate; attaching the first die to a wafer, the wafer and the first die being electrically connected; and attaching a second die to the first die, the first die being electrically interposed between the wafer and the second die. In another embodiment, an active side of the second die faces the front-side of the substrate of the first die. In another embodiment, the method further includes, after attaching the second die to the first die: forming a third interconnect structure over a back-side of the wafer; and forming external connectors over the third interconnect structure and over the back-side of the wafer. In another embodiment, forming the first die comprises forming a plurality of first dies at a wafer level, wherein attaching the first die to the wafer comprises attaching the plurality of first dies to the wafer, wherein after attaching the second die to the first die, the second die is electrically connected to each die of the plurality of first dies. In another embodiment, attaching the second die to the first die comprises attaching a plurality of second dies to the first die, and wherein each die of the plurality of second dies is electrically connected to the first die. In another embodiment, forming the first die comprises forming a plurality of first dies at a wafer level, further comprising attaching an additional first die to the first die, wherein the first die is electrically interposed between the wafer and the additional first die, and wherein attaching the second die to the first die comprises attaching the second die to the additional first die.

In an embodiment, a semiconductor package includes: a first transistor over a front-side of a first substrate; a first conductive via extending from the front-side to a back-side of the first substrate, the first conductive via having a first width measured at the front-side of the first substrate and a second width measured at the back-side of the first substrate, the first width being greater than the second width; a second conductive via extending from the front-side to the back-side of the first substrate, the second conductive via having a third width measured at the front-side of the first substrate and a fourth width measured at the back-side of the first substrate, the third width being greater than the fourth width, the third width being greater than the first width of the first conductive via; a third conductive via extending from the first transistor to the back-side of the first substrate, the third conductive via having a fifth width measured at the first transistor and a sixth width measured at the back-side of the first substrate, the fifth width being less than the sixth width; a first interconnect structure over the first transistor and the front-side of the first substrate; a first bond pad over the first interconnect structure, the first bond pad being bonded to a second bond pad of a first die; a second interconnect structure over the back-side of the first substrate, the third conductive via electrically connecting the second interconnect structure to the first transistor; a third bond pad over the second interconnect structure, the third bond pad being bonded to a fourth bond pad of a second die; and an external connector along a back-side of the second die, the back-side of the second die being opposite of the fourth bond pad. In another embodiment, the first die comprises a second transistor over an active side of a second substrate, the active side of the second substrate facing the front-side of the first substrate. In another embodiment, the second die comprises a third transistor over an active side of a third substrate, the active side of the third substrate facing the back-side of the first substrate. In another embodiment, the first width of the first conductive via is greater than the sixth width of the third conductive via. In another embodiment, the semiconductor package further includes: a buried contact embedded in the front-side of the first substrate; and a fourth conductive via extending from the buried contact to the back-side of the first substrate, the fourth conductive via having a seventh width measured at the buried contact and an eighth width measured at the back-side of the first substrate, the seventh width being less than the eighth width. In another embodiment, the sixth width of the third conductive via is the same as the eighth width of the fourth conductive via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
a first transistor over a front-side of a first substrate;
a first conductive via extending from the front-side to a back-side of the first substrate, the first conductive via having a first width measured at the front-side of the first substrate and a second width measured at the back-side of the first substrate, the first width being greater than the second width;
a second conductive via extending from the front-side to the back-side of the first substrate, the second conductive via having a third width measured at the front-side of the first substrate and a fourth width measured at the back-side of the first substrate, the third width being greater than the fourth width, the third width being greater than the first width of the first conductive via;
a third conductive via extending from the first transistor to the back-side of the first substrate, the third conductive via having a fifth width measured at the first transistor and a sixth width measured at the back-side of the first substrate, the fifth width being less than the sixth width;
a first interconnect structure over the first transistor and the front-side of the first substrate;
a first bond pad over the first interconnect structure, the first bond pad being bonded to a second bond pad of a first die;
a second interconnect structure over the back-side of the first substrate, the third conductive via electrically connecting the second interconnect structure to the first transistor;
a third bond pad over the second interconnect structure, the third bond pad being bonded to a fourth bond pad of a second die; and
an external connector along a back-side of the second die, the back-side of the second die being opposite of the fourth bond pad.

2. The semiconductor package of claim 1, wherein the first die comprises a second transistor over an active side of a second substrate, the active side of the second substrate facing the front-side of the first substrate.

3. The semiconductor package of claim 2, wherein the second die comprises a third transistor over an active side of a third substrate, the active side of the third substrate facing the back-side of the first substrate.

4. The semiconductor package of claim 1, wherein the first width of the first conductive via is greater than the sixth width of the third conductive via.

5. The semiconductor package of claim 1, further comprising:
a buried contact embedded in the front-side of the first substrate; and
a fourth conductive via extending from the buried contact to the back-side of the first substrate, the fourth conductive via having a seventh width measured at the buried contact and an eighth width measured at the back-side of the first substrate, the seventh width being less than the eighth width.

6. The semiconductor package of claim 5, wherein the sixth width of the third conductive via is the same as the eighth width of the fourth conductive via.

7. The semiconductor package of claim 1, wherein the third conductive via is connected to a source/drain region of the first transistor.

8. The semiconductor package of claim 1, wherein the first bond pad is bonded to the second bond pad through a metal-to-metal bond, wherein the first bond pad is embedded in a first dielectric bond layer, wherein the second bond pad is embedded in a second dielectric bond layer, and wherein the first dielectric bond layer is bonded to the second dielectric bond layer through a dielectric-to-dielectric bond.

9. The semiconductor package of claim 8, wherein the dielectric-to-dielectric bond comprises silicon-nitrogen-silicon chemical bonds.

10. A semiconductor package comprising:
a first semiconductor die comprising:
a first transistor along a front-side of a first substrate;
first lower metallization layers of a first interconnect structure over the first transistor;
first upper metallization layers of the first interconnect structure over the first lower metallization layers;
a first conductive via extending from the first upper metallization layers, through the front-side of the first substrate, and to a back-side of the first substrate; and
a first bond layer over the first upper metallization layers, the first bond layer comprising a first bond via and a first bond pad disposed in first dielectric layers;
a second semiconductor die over the first semiconductor die, the second semiconductor die comprising:
a second bond layer bonded to the first bond layer, the second bond layer comprising a second bond via and a second bond pad disposed in second dielectric layers;
a second interconnect structure over the second bond layer;
a second substrate over the second interconnect structure, a front-side of the second substrate facing away from the first semiconductor die;
a second transistor along the front-side of the second substrate;
a third interconnect structure over the second transistor;
a second conductive via extending from the front-side of the second substrate to a back-side of the second substrate; and
a third conductive via extending from the third interconnect structure to the back-side of the second substrate.

11. The semiconductor package of claim 10, wherein the second semiconductor die further comprises a buried contact along the front-side of the second substrate, and wherein a fourth conductive via extends from the back-side of the second substrate to the buried contact.

12. The semiconductor package of claim 11, where in a taper of the second conductive via has an opposite direction than a taper of the third conductive via.

13. The semiconductor package of claim 10, wherein the second semiconductor die further comprises a third bond layer over the third interconnect structure, and wherein the third bond layer comprises a third bond via and a third bond pad disposed in third dielectric layers.

14. The semiconductor package of claim 13, further comprising a third semiconductor die over the second semiconductor die, wherein the third semiconductor die comprises a fourth bond layer, wherein the fourth bond layer comprises a fourth bond via and a fourth bond pad disposed in fourth dielectric layers, wherein the third bond pad and the fourth bond pad have a direct metal-to-metal bond, and wherein the third dielectric layers and the fourth dielectric layers have a direct dielectric-to-dielectric bond.

15. A semiconductor package comprising:
a bottom die comprising:
a first substrate having a front-side and a back-side opposite the front-side;
a first integrated circuit comprising a plurality of first devices at the front-side of the first substrate; and
a first interconnect structure on the front-side of the first substrate, the first interconnect structure electrically connecting the plurality of first devices of the first integrated circuit;
a middle die attached to the bottom die, the middle die comprising:
a second substrate having a front-side and a back-side opposite the front-side of the second substrate, the back-side of the second substrate facing the front-side of the first substrate;
a second integrated circuit disposed at the front-side of the second substrate;
a second interconnect structure on the front-side of the second substrate;
a third interconnect structure on the back-side of the second substrate; and
one or more conductive vias extending through the second substrate and electrically connecting the second interconnect structure to the third interconnect structure, wherein the third interconnect structure of the middle die is bonded to the first interconnect structure of the bottom die through a combination of dielectric-to-dielectric bonding and metal-to-metal bonding, without an adhesive disposed between the middle die and the first substrate;
a top die attached to the middle die, the top die comprising:
a third substrate having a front-side and a back-side opposite the front-side of the third substrate, the front-side of the third substrate facing the front-side of the second substrate;
a third integrated circuit comprising a plurality of second devices at the front-side of the third substrate; and a fourth interconnect structure on the front-side of the third substrate, the fourth interconnect structure electrically connecting the plurality of second devices of the third integrated circuit, wherein the fourth interconnect structure of the top die is bonded to the second interconnect structure of the middle die through a combination of dielectric-to-dielectric bonding and metal-to-metal bonding, without an adhesive disposed between the top die and the middle die; and an encapsulant disposed around the middle die and around the top die, the encapsulant extending between the bottom die and the top die.

16. The semiconductor package of claim 15, wherein the bottom die further comprises a fifth interconnect structure on the back-side of the first substrate and one or more through-substrate vias extending through the first substrate and electrically connecting the first interconnect structure to the fifth interconnect structure, wherein the semiconductor package further comprises a plurality of external connectors on the fifth interconnect structure and opposite the first substrate from the first interconnect structure.

17. The semiconductor package of claim 15, wherein the one or more conductive vias of the middle die comprise a first via extending into the second substrate from the front-side of the second substrate and a second via extending through the second interconnect structure into the second substrate, wherein the first via has an uppermost width less than or equal to an uppermost width of the second via.

18. The semiconductor package of claim 15, further comprising a second middle die attached to the bottom die adjacent the middle die and a second top die attached to the second middle die, wherein the top die is electrically connected to the second top die only indirectly, through the bottom die.

19. The semiconductor package of claim 15, wherein the first integrated circuit comprises a logic die and the second integrated circuit comprises a memory die.

20. The semiconductor package of claim 15, wherein the third interconnect structure comprises a first dielectric bond layer and a plurality of first bond pads embedded in the first dielectric bond layer, wherein the first interconnect structure comprises a second dielectric bond layer and a plurality of second bond pads embedded in the second dielectric bond layer, wherein the plurality of first bond pads directly contact the plurality of second bond pads, and wherein the first dielectric bond layer directly contacts the second dielectric bond layer.
